(19) United States
(12) Patent Application Publication
(10) Pub. No.: US 2015/0137829 A1
(43) Pub. Date: May 21, 2015

(54) ELECTROMAGNETIC ANECHOIC CHAMBER

(71) Applicant: HON HAI PRECISION INDUSTRY CO., LTD., New Taipei (TW)

(72) Inventor: TEN-CHEN HO, New Taipei (TW)

(73) Assignee: HON HAI PRECISION INDUSTRY CO., LTD., New Taipei (TW)

(21) Appl. No.: 14/144,600

(22) Filed: Dec. 31, 2013

(30) Foreign Application Priority Data
Nov. 21, 2013 (CN) 2013105889718

(51) Int. Cl. G01R 29/08

(52) U.S. Cl. CPC G01R 29/0821; G01R 29/0835
USPC 324/627

(57) ABSTRACT

An electromagnetic anechoic chamber includes a chamber, a test bench located in the chamber for supporting an electronic device, a horizontal high frequency antenna, a perpendicular high frequency antenna, a horizontal low frequency antenna, a perpendicular low frequency antenna, four directional filters, four relays, a mixer, and a receiver. The horizontal high frequency antenna, the perpendicular high frequency antenna, the horizontal low frequency antenna, and the perpendicular low frequency antenna are located around the platform, and electrically coupled to the directional filters. Each relay includes a first end connected to the mixer and a second end connected to the corresponding directional filter. The mixer is electrically coupled to the receiver. The mixer generates a composite signal. The composite signal is transmitted to the receiver. The receiver analyzes and displays whether the electronic device is qualified or not.

### BACKGROUND

1. Technical Field

The present disclosure relates to electromagnetic anechoic chambers, and particularly to an electromagnetic anechoic chamber with an electromagnetic interference (EMI) test apparatus.

2. Description of Related Art

At present, electronic products need to be tested for EMI in an electromagnetic anechoic chamfer. During the tests, a horizontal high frequency antenna, a perpendicular high frequency antenna, a horizontal low frequency antenna, and a perpendicular low frequency antenna are used to test each electronic product, and the switch between every two antennas needs to be achieved manually. Therefore, the test is inconvenient and easily leads to an inaccurate test results.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an isometric view of an embodiment of an electromagnetic anechoic chamber.

FIG. 2 is a block diagram of the electromagnetic anechoic chamber of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean “at least one.”

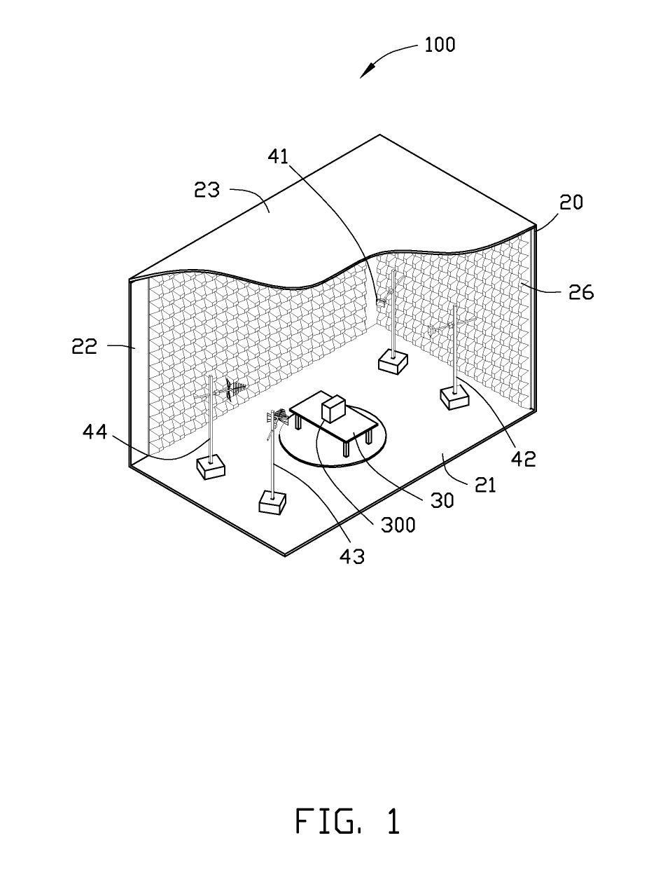

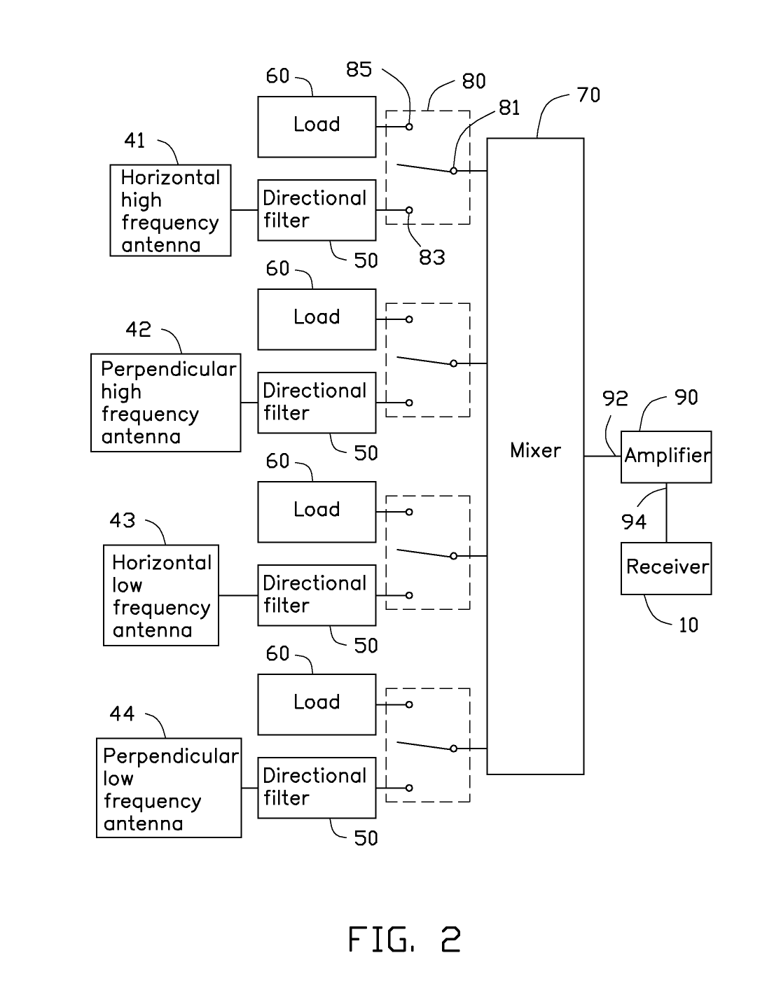

FIGS. 1 and 2 show an embodiment of an electromagnetic anechoic chamber 100 for testing an electronic device 300. The electromagnetic anechoic chamber 100 comprises a chamber 20, a test bench 30 located in the chamber 20, a horizontal high frequency antenna 41, a perpendicular high frequency antenna 42, a horizontal low frequency antenna 43, a perpendicular low frequency antenna 44, four directional filters 50, four loads 60, a mixer 70, four relays 80, an amplifier 90, and a receiver 10. In the embodiment, the electronic device 300 is a mobile phone or a computer.

The chamber 20 comprises a rectangular bottom wall 21, a sidewall 22 perpendicularly extending up from sides of the bottom wall 21, and a top wall 23. Electromagnetic wave absorptive material 26 is spread on inner surfaces of the sidewall 22 and the top wall 23. The test bench 30 is rotatably located above a middle of the bottom wall 21. The horizontal high frequency antenna 41, the perpendicular high frequency antenna 42, the horizontal low frequency antenna 43, and the perpendicular low frequency antenna 44 are located around the test bench 30. The horizontal high frequency antenna 41, the perpendicular high frequency antenna 42, the horizontal low frequency antenna 43, and the perpendicular low frequency antenna 44 all face the test bench 30.

The horizontal high frequency antenna 41, the perpendicular high frequency antenna 42, the horizontal low frequency antenna 43, and the perpendicular low frequency antenna 44 are electrically coupled to the directional filters 50, respectively. Each relay 80 comprises a first end 81 electrically coupled to the mixer 70, a second end 83 electrically coupled to the corresponding directional filter 50, and a third end 85 electrically coupled to a corresponding load 60. A resistance of each load 60 is equal to a resistance of the corresponding directional filter 50, to allow the load 60 and the corresponding directional filter 50 to match impedance. In the embodiment, each load 60 is a resistor, and the resistance of each load 60 is 50 ohms. When the first ends 81 of the relays 80 are coupled to the corresponding third ends 85, the horizontal high frequency antenna 41, the perpendicular high frequency antenna 42, the horizontal low frequency antenna 43, and the perpendicular low frequency antenna 44 stop operating.

In use, the first ends 81 of the relays 80 are electrically coupled to the corresponding second ends 83. The horizontal high frequency antenna 41, the perpendicular high frequency antenna 42, the horizontal low frequency antenna 43, and the perpendicular low frequency antenna 44 synchronously receive electromagnetic signals from the operating electronic device 300. The electromagnetic signals are transmitted to the mixer 70 by the directional filters 50 and the relays 80. The amplifier 90 comprises an input 92 electrically coupled to the mixer 70 and an output 94 electrically coupled to the receiver 10. The mixer 70 receives the electromagnetic signals from the directional filters 50, generates a composite signal, and then transmits the composite signal to the amplifier 90. The composite signal is amplified to an amplified signal through the amplifier 90. The receiver 10 receives and analyzes the amplified signal from the amplifier 90, and determines whether the electronic device 300 is qualified or not.

In testing the electronic device 300 about electromagnetic interference, the electronic device 300 is placed on the test bench 30, and is powered. The relays 80 connect the mixer 70 to the directional filters 50, and the horizontal high frequency antenna 41, the perpendicular high frequency antenna 42, the horizontal low frequency antenna 43, and the perpendicular low frequency antenna 44 synchronously receive electromagnetic signals from the electronic device 300. The horizontal high frequency antenna 41, the perpendicular high frequency antenna 42, the horizontal low frequency antenna 43, and the perpendicular low frequency antenna 44 convert the electromagnetic signals into voltage signals, and then transmit the voltage signals to the mixer 70 through the directional filters 50 and the relays 80. The mixer 70 synthesizes the voltage signals to a composite signal, and transmits the composite signal to the amplifier 90. The amplifier 90 amplifies the composite signal, and transmits an amplified signal to the receiver 10.

The receiver 10 compares the high frequency and the low frequency of the amplified signal with a predetermined value. In addition, determines whether the high frequency of the amplified signal, the low frequency of the amplified signal, or both of the high frequency of the amplified signal and the low frequency of the amplified signal are less than the predetermined value.

If both of the high frequency and the low frequency are less than the predetermined value, it means that the electronic device 300 is qualified.

If the high frequency is greater than or equal to the predetermined value, the mixer 70 is disconnected from the horizontal low frequency antenna 43, the perpendicular low frequency antenna 44, and the perpendicular high frequency antenna 42. The mixer 70 is connected to the horizontal high frequency antenna 41 through the corresponding relay 80, and is connected to the corresponding loads 60 through the other relays 80. The horizontal high frequency antenna 41 receives the electromagnetic signal from the electronic device 300, converts the electromagnetic signal into the voltage signal, and then transmits the voltage signal to the amplifier 90 through the corresponding directional filter 50, the relay 80, and the mixer 70. The amplifier 90 amplifies the voltage signal, and transmits an amplified signal to the receiver 10. The receiver 10 compares the horizontal high frequency of the amplified signal with the predetermined value, and determines whether the horizontal high frequency of the electronic device is less than the predetermined value. If the horizontal high frequency is less than the predetermined value, it means the perpendicular high frequency of the electronic device 300 is greater than or equal to the predetermined value. If the horizontal high frequency is greater than or equal to the predetermined value, the perpendicular high frequency of the electronic device 300 needs to be analyzed.

The mixer 70 is disconnected from the horizontal low frequency antenna 43, the perpendicular low frequency antenna 44, and the horizontal high frequency antenna 41. The mixer 70 is connected to the perpendicular high frequency antenna 42 through the corresponding relay 80, and is connected to the corresponding loads 60 through the other relays 80. The perpendicular high frequency antenna 42 receives the electromagnetic signal from the electronic device 300, converts the electromagnetic signal into the voltage signal, and then transmits the voltage signal to the amplifier 90 through the corresponding directional filter 50, the relay 80, and the mixer 70. The amplifier 90 amplifies the voltage signal, and transmits an amplified signal to the receiver 10. The receiver 10 compares the perpendicular high frequency of the amplified signal with the predetermined value, and determines whether the perpendicular high frequency of the electronic device is less than the predetermined value.

If the low frequency is greater than or equal to the predetermined value, the mixer 70 is disconnected from the horizontal high frequency antenna 41, the perpendicular high frequency antenna 42, and the perpendicular low frequency antenna 44. The mixer 70 is connected to the horizontal low frequency antenna 43 through the corresponding relay 80, and is connected to the corresponding loads 60 through the other relays 80. The horizontal low frequency antenna 43 receives the electromagnetic signal from the electronic device 300, converts the electromagnetic signal into the voltage signal, and then transmits the voltage signal to the amplifier 90 through the corresponding directional filter 50, the relay 80, and the mixer 70. The amplifier 90 amplifies the voltage signal, and transmits an amplified signal to the receiver 10. The receiver 10 compares the horizontal low frequency of the amplified signal with the predetermined value, and determines whether the horizontal low frequency of the electronic device 300 is less than the predetermined value. If the horizontal low frequency is less than the predetermined value, it means the perpendicular low frequency of the electronic device 300 is greater than or equal to the predetermined value. If the horizontal low frequency of the electronic device 300 is greater than or equal to the predetermined value, the perpendicular low frequency of the electronic device 300 needs to be analyzed.

The mixer 70 is disconnected from the horizontal high frequency antenna 41, the perpendicular high frequency antenna 42, and the horizontal low frequency antenna 43. The mixer 70 is connected to the perpendicular low frequency antenna 44 through the corresponding relay 80, and is connected to the corresponding loads 60 through the other relays 80. The perpendicular low frequency antenna 44 receives the electromagnetic signal from the electronic device 300, converts the electromagnetic signal into the voltage signal, and then transmits the voltage signal to the amplifier 90 through the corresponding directional filter 50, the relay 80, and the mixer 70. The amplifier 90 amplifies the voltage signal, and transmits an amplified signal to the receiver 10. The receiver 10 compares the perpendicular low frequency of the amplified signal with the predetermined value, and determines whether the perpendicular low frequency of the electronic device is less than the predetermined value.

If both the high frequency and the low frequency are greater than or equal to the predetermined value, the horizontal high frequency antenna 41, the perpendicular high frequency antenna 42, the horizontal low frequency antenna 43, and the perpendicular low frequency antenna 44 respectively test the electronic device 300.

Even though numerous characteristics and advantages of the embodiments have been set forth in the foregoing description, together with details of the structure and function of the embodiments, the present disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. An electromagnetic anechoic chamber, comprising:
a chamber;
a test bench located in the chamber for supporting an electronic device;
a horizontal high frequency antenna;
a perpendicular high frequency antenna;
a horizontal low frequency antenna;
a perpendicular low frequency antenna;
four directional filters electrically coupled to the horizontal high frequency antenna, the perpendicular high frequency antenna, the horizontal low frequency antenna, and the perpendicular low frequency antenna;
a receiver;
a mixer coupled to the receiver; and
four relays, each relay comprising a first end electrically coupled to the mixer, and a second end electrically coupled to a corresponding directional filter;
wherein the horizontal high frequency antenna, the perpendicular high frequency antenna, the horizontal low frequency antenna, and the perpendicular low frequency antenna are located around the test bench, when the first ends of the relays are coupled to the second ends, the horizontal high frequency antenna, the perpendicular high frequency antenna, the horizontal low frequency antenna, and the perpendicular low frequency antenna receive electromagnetic signals, the electromagnetic signals are transmitted to the mixer by the direction filters, the mixer receives the electromagnetic signals, generates a composite signal, and transmits the composite signal to the receiver, the receiver analyzes and displays whether the electromagnetic signal is qualified or not.

2. The electromagnetic anechoic chamber of claim 1, further comprising four loads, wherein each relay further comprises a third end coupled to a corresponding load.

3. The electromagnetic anechoic chamber of claim 2, wherein when the first ends of the relays are coupled to the third ends, the horizontal high frequency antenna, the perpendicular high frequency antenna, the horizontal low frequency antenna, and the perpendicular low frequency antenna stop operating.

4. The electromagnetic anechoic chamber of claim 2, wherein each load is a resistor.

5. The electromagnetic anechoic chamber of claim 2, wherein a resistance of each load is equal to a resistance of the corresponding directional filter.

6. The electromagnetic anechoic chamber of claim 1, further comprising an amplifier coupled between the mixer and the receiver.

7. The electromagnetic anechoic chamber of claim 6, wherein the amplifier receives the composite signal from the mixer and amplifies the composite signal.

8. The electromagnetic anechoic chamber of claim 1, wherein the chamber comprises a bottom wall, a sidewall extending up from sides of the bottom wall, and a top wall, electromagnetic wave absorptive material is spread on inner surfaces of the sidewall and the top wall, the test bench is located above the bottom wall.
